(19) United States
(12) Patent Application Publication
(10) Pub. No.: US 2007/0284609 A1
(43) Pub. Date: Dec. 13, 2007

(54) METHOD AND APPARATUS FOR DRAIN PUMP POWER CONSERVATION

(76) Inventors: Boon-Aik Ang, Santa Clara, CA (US); Nian Yang, Mountain View, CA (US); Yonggang Wu, Santa Clara, CA (US)

Correspondence Address: INGRASSIA FISHER & LORENZ, P.C., 7150 E. CAMELBACK, STE. 325, SCOTTSDALE, AZ, 85251, US

(21) Appl. No.: 11/423,649

(22) Filed: Jun. 12, 2006

(51) Int. Cl. H01L 29/74

(52) U.S. Cl. 257/139

(57) ABSTRACT

A method and apparatus are provided for improved power conservation in a semiconductor device (100) which includes a high voltage generating circuit (200) such as a drain pump. The operation frequency of the drain pump (200) is controlled in response to the high voltage level detected at the output thereof. In addition, highly efficient operation of the drain pump (200) can be achieved by enabling and disabling the drain pump (200) in response to the high voltage level to provide an output signal at a relatively constant high voltage level. The drain pump (200) is enabled in response to a high voltage detector (202, 402, 502) detecting a high voltage level lower than a first predetermined voltage level and is disabled in response to detecting a voltage level higher than a second predetermined voltage level, the second predetermined voltage level being higher than the first predetermined voltage level.

### FIELD OF THE INVENTION

The present invention generally relates to semiconductor high voltage generating circuits such as drain pumps, and more particularly relates to a method and apparatus for drain pump power conservation.

### BACKGROUND OF THE INVENTION

Drain pumps and similar high voltage generating circuits are utilized to provide high voltage and/or high current for semiconductor device operation. For example, in semiconductor memory devices, drain pumps are used to provide high voltage and high current for programming memory cells. Drain pumps consume large amounts of the power consumed by the semiconductor devices. Current consumption by drain pumps is one of the primary reasons that such power is consumed by the drain pumps. In addition inefficient drain pump operation, which can be measured by dividing the output power by the input power, contributes to further power consumption.

Accordingly, it is desirable to provide a method and apparatus for improved drain pump operation which conserves power by reducing current consumption and maintaining high efficiency operation. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method and apparatus is provided for improved power conservation in a semiconductor device which includes a high voltage generating circuit such as a drain pump. The operation frequency of the drain pump is controlled in response to the high voltage level detected at the output thereof. In addition, highly efficient operation of the drain pump can be achieved by enabling and disabling the drain pump in response to the high voltage level to provide an output signal at a relatively constant high voltage level. The drain pump is enabled in response to detecting a high voltage level lower than a first predetermined voltage level and is disabled in response to detecting a voltage level higher than a second predetermined voltage level, the second predetermined voltage level being higher than the first predetermined voltage level.

### BRIEF DESCRIPTION OF THE DRAWINGS

The present invention will hereinafter be described in conjunction with the following drawing figures, wherein like numerals denote like elements, and

FIG. 1 is a block diagram of a semiconductor memory device in accordance with the present invention;

FIG. 2 is a high voltage generator in accordance with a first embodiment of the present invention;

FIG. 3 is a graph showing the variation of the operational frequency in relation to a received control voltage signal of a voltage control oscillator in accordance with the first embodiment of the present invention;

FIG. 4 is a high voltage generator in accordance with a second embodiment of the present invention;

FIG. 5 is a high voltage generator in accordance with a third embodiment of the present invention; and

FIG. 6 is a flowchart of a method for efficient drain pump operation in accordance with the second embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

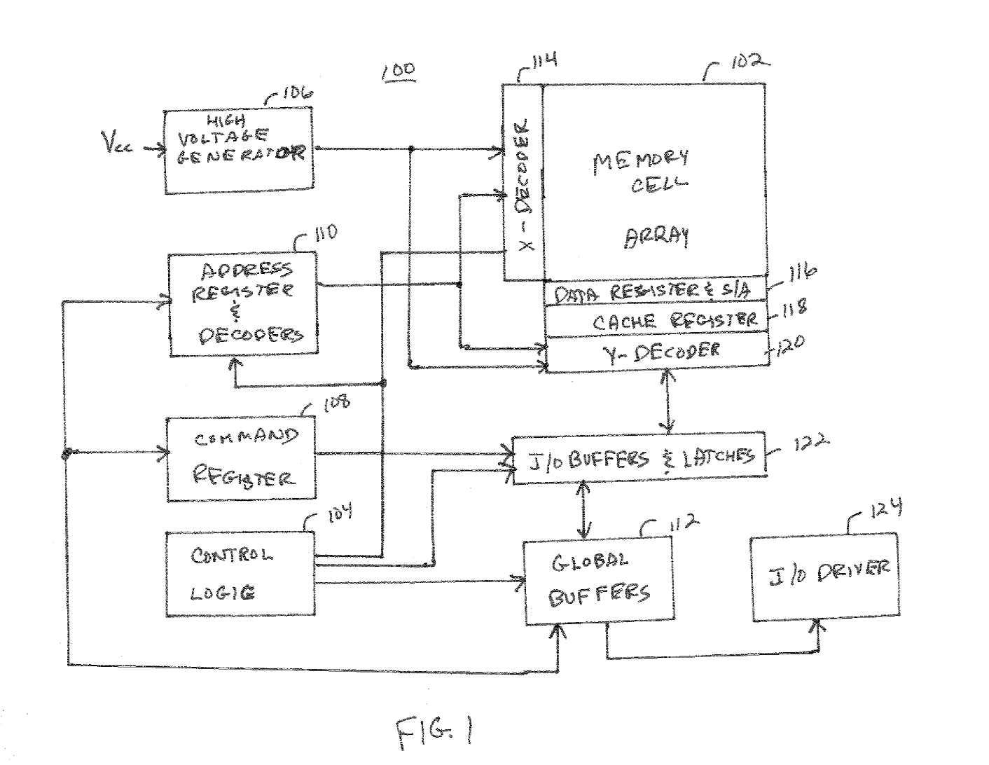

Referring to FIG. 1, a non-volatile semiconductor memory device 100, such as a flash memory device, includes a memory cell array 102, control logic 104 such as a state machine, a high-voltage generator 106, a command register 108, an address register and decoder 110, a global buffer 112, an X-decoder 114, a data register and sense amplifier 116, a cache register 118, a Y-decoder 120, an Input/Output (I/O) buffer and latch circuit 122, and an input/output driver 124.

The memory cell array 102 includes rewritable non-volatile memory cells that are arranged along word lines and bit lines in a matrix fashion well-known to those skilled in the art. Each of the memory cells is a cell wherein the write function is performed through hot electron injection. In this embodiment, SONOS-type cells may be employed as the non-volatile memory cells. The state machine 104 controls the operation of each circuit in the device in response to each control signal.

In accordance with the present invention, the high-voltage generator 106 generates voltage signals having high voltage levels that are used within the semiconductor device for memory operations thereof by applying the high voltages to selected cells within the memory cell array 102 via the X-Decoder 114 and the Y-Decoder 120. The high voltage signals used within the semiconductor memory device include voltage signals with a high voltage level for writing data, a high voltage level for erasing data, a high voltage level for reading data, and a verifying high voltage level for checking whether sufficient write/erase has been performed on a subject memory cell at the time of writing or erasing data.

The command register 108 temporarily stores operation commands that are input through the global buffer 112. The address register and decoder 110 temporarily stores input address signals. The I/O buffer and latch circuit 122 controls various signals or data corresponding to I/O terminals. The input/output driver 124 controls the data to be output from the semiconductor memory device 100 and the data to be input thereto.

Referring to FIG. 2, a high-voltage generator 106 in accordance with a first embodiment of the present invention includes a high voltage generating circuit 200, such as a drain pump, for generating voltage signals having a high voltage. A voltage level detector 202 is coupled to the output of the drain pump 200 and generates a voltage control signal in response to the high voltage level detected at the output of the drain pump 200. In accordance with this first embodiment of the present invention, the voltage control signal (VCTRL) is an analog signal generated by a voltage level detector 200 such as a simple resistor divider circuit and is provided to a controller 203. More particularly, the voltage control signal is provided to a voltage controlled oscillator (VCO) 204 within the controller 203. The VCO 204 is coupled to the drain pump 200 and generates an operating clock signal to adjust an operation frequency of the drain pump 200.

Referring to FIG. 3, a graph shows the variation of the operational frequency (FREQ) in relation to the voltage control signal (VCTRL) of the VCO 204 in accordance with the first embodiment of the present invention. The VCO 204 functions to maintain the drain pump 200 within predefined operation frequencies (between a maximum operation frequency (FREQ_{MIN}) and a minimum operation frequency (FREQ_{MAX})) to keep the high voltage level within an optimal range. Thus, as the voltage control signal (VCTRL) varies between a maximum value (VCTRL_{MIN}) and a minimum value (VCTRL_{MAX}), the VCO 204 adjusts the operation frequency of the drain pump 200 by reducing the operation frequency of the drain pump when the voltage control signal indicates an increase in the high voltage level to reduce power consumption of the drain pump 200. In addition, the VCO 204 increases the operation frequency of the drain pump 200 in response to the voltage level detector 202 detecting a decrease in the high voltage level to quickly restore the voltage signals to the optimum high voltage level, thereby increasing reliability of the high voltage generator 106.

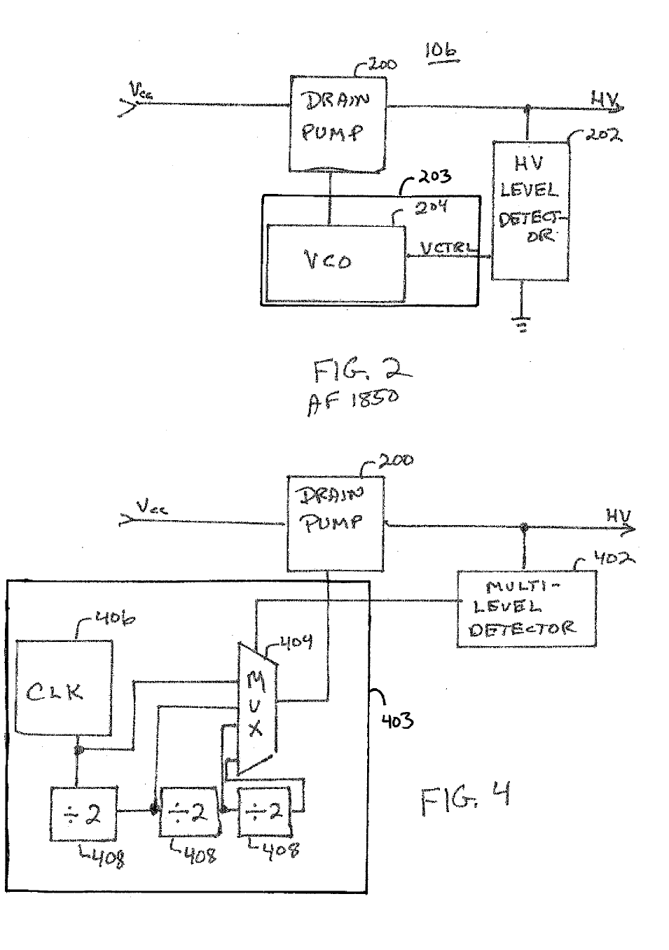

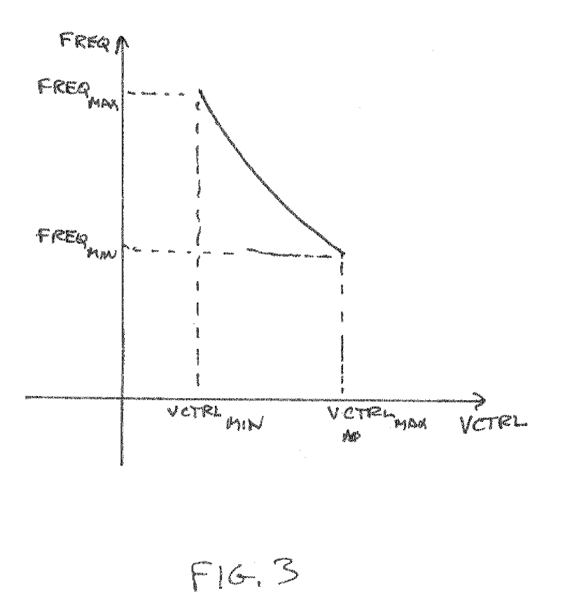

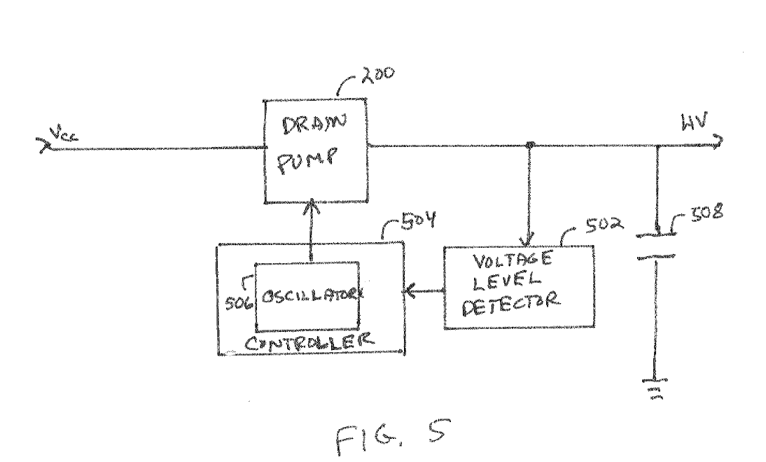

Referring to FIG. 4, a high-voltage generator 106 in accordance with a second embodiment of the present invention includes the drain pump 200 for generating the voltage signals having a high voltage. A multi-level voltage detector 402 is coupled to the output of the drain pump 200 and generates a clock selection signal in response to the high voltage level detected at the output of the drain pump 200. In accordance with this second embodiment of the present invention, the clock selection signal is provided to a clock signal selector 404, such as a multiplexer, within a controller 403. The controller also includes a clock 406 and multiple clock signal dividers 408.

A plurality of clock signals are provided to the multiplexer 404. The plurality of clock signals are generated by a base clock signal from the clock 406 passing through the multiple clock signal dividers 408, such as frequency dividers, coupled in series. The plurality of signals are tapped from the output of the clock 406 and the clock signal dividers 408. Therefore, depending on the high voltage level detected by the multi-level detector 402, different ones of the plurality of clock signals are selected to control the operation frequency of the drain pump 200. In this manner, lower frequency clock signals could be selected to achieve high voltage generator 106 current savings, thereby providing a method for power conservation in the semiconductor 100.

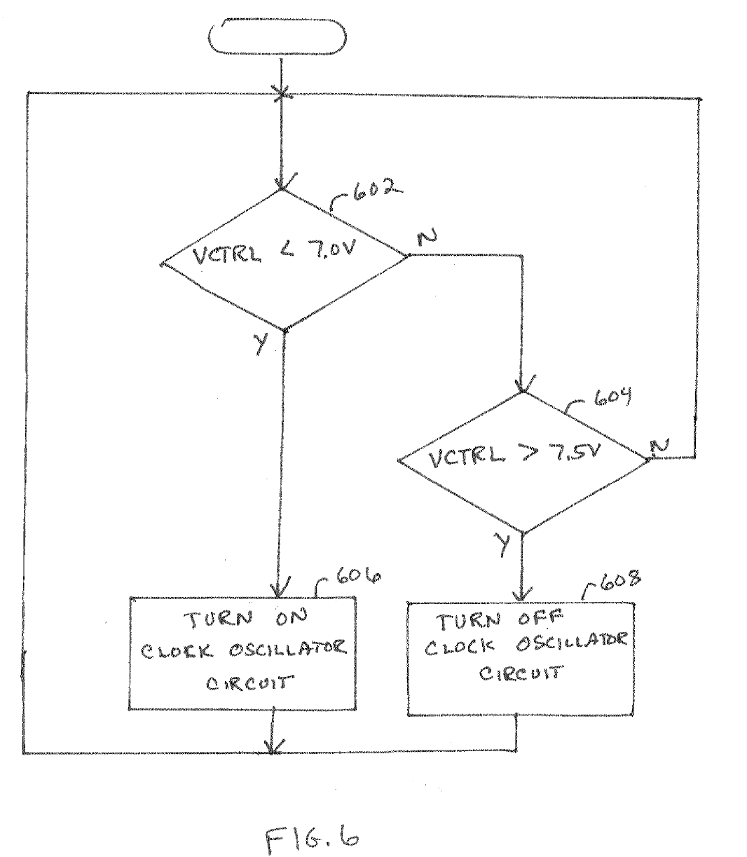

Efficient operation of the high voltage generator 106 provides both power conservation and reliable operation. Referring to FIG. 5, a high voltage generator 106 in accordance with a third embodiment of the present invention outputs voltage signals having a relatively constant high voltage level to achieve high efficiency in the operation thereof. It is well known that the high voltage level of the output voltage signals changes greatly with current loading affecting the efficiency of the high voltage generator 106. When the current is low and the voltage is high, efficiency is also low. In fact, efficiency is high and almost constant only within a thin voltage range.

To achieve high and almost constant efficiency, the high voltage generator 106 includes a voltage level detector 502 coupled to the output of a drain pump 200 for detecting a high voltage level of the voltage signals generated by the drain pump 200 and generating a voltage control signal in response thereto. The voltage level detector 502 is coupled to a controller 504 which includes a clock oscillator circuit 506 for providing an operation frequency control signal to the drain pump 200. In addition, a large capacitor 508 is coupled between ground and the voltage signals having a high voltage level to provide output current when the drain pump 200 is disabled.

Referring to FIG. 6, a flowchart of the operation of the controller 504 in accordance with the third embodiment of the present invention begin by examining the voltage control signal to determine whether the high voltage level is lower than a first predetermined voltage level 602 or higher than a second predetermined voltage 604. The second predetermined voltage level is higher than the first predetermined voltage level. In accordance with a semiconductor device such as a non-volatile memory device (e.g., a Flash memory device), the second predetermined voltage level and the first predetermined voltage level differ by 0.5 volts and, preferably, are 7.5 volts and 7.0 volts, respectively.

If the voltage control signal indicates the detected high voltage level is lower than the first predetermined voltage level 602, the drain pump 200 is enabled 606 by turning on the clock oscillator circuit 506. Conversely, if the voltage control signal indicates the detected high voltage level is higher than the second predetermined voltage level 602, the drain pump 200 is disabled 608 by turning off the clock oscillator circuit 506. Operation then returns to detect the next change in the high voltage level.

While operation in accordance with the third embodiment of the present invention provides relatively constant output voltage to achieve high efficiency, combination of the operation of the third embodiment with the power conservation techniques of the first or second embodiment of the present invention will result in additional power savings and improved operational efficiency of the semiconductor device 100.

While at least one exemplary embodiment has been presented in the foregoing detailed description of the invention, it should be appreciated that a vast number of variations exist. For example, the description above describes a semiconductor memory device embodiment of the present invention. However, the present invention is not limited to this embodiment and the high voltage generator 106 could be implemented in any semiconductor device to provide the benefits and advantages of the present invention for the operation thereof. It should also be appreciated that the exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the claims. Accordingly, the scope of the present invention is only limited by the claims hereinbelow and their equivalents.

What is claimed is:

1. A method of power conservation in a semiconductor device comprising a high voltage generating circuit for generating a high voltage level, the method comprising the steps of:
detecting the high voltage level; and
controlling an operation frequency of the high voltage generating circuit in response to the high voltage level detected.

2. The method of claim 1 wherein the step of detecting the high voltage comprises the step of generating a voltage control signal in response to the high voltage level detected.

3. The method of claim 2 wherein the step of controlling an operation frequency of the high voltage generating circuit comprises the steps of:
generating an operating clock signal in response to the voltage control signal; and
providing the operating clock signal to the high voltage generating circuit for controlling the operation frequency thereof.

4. The method of claim 2 wherein the step of controlling an operation frequency of the high voltage generating circuit comprises the steps of:
selecting an operating clock signal of one of a plurality of clock signal generators in response to the voltage control signal; and
providing the selected operating clock signal to the high voltage generating circuit for controlling the operation frequency thereof.

5. A semiconductor device comprising:
a high voltage generating circuit for generating a high voltage level;
a voltage level detector coupled to the output of the high voltage generating circuit for generating a voltage control signal in response to the high voltage level detected thereat; and
a controller coupled to the voltage level detector and the high voltage generating circuit to control an operation frequency of the high voltage generating circuit in response to the voltage control signal.

6. The semiconductor device of claim 5 wherein the controller comprises a voltage controlled oscillator for generating an operating clock signal in response to the voltage control signal, and wherein the operation frequency of the high voltage generating circuit is adjusted in response to the operating clock signal.

7. The semiconductor device of claim 5 wherein the operation frequency of the high voltage generating circuit is reduced in response to the voltage control signal indicating that the voltage level detector detected a high voltage level greater than a predetermined high voltage level to reduce power consumption of the high voltage generating circuit.

8. The semiconductor device of claim 5 wherein the operation frequency of the high voltage generating circuit is increased in response to the voltage control signal indicating that the voltage level detector detected a high voltage level less than a predetermined high voltage level to increase reliability of the high voltage generating circuit.

9. The semiconductor device of claim 5 wherein the semiconductor device is a non-volatile memory semiconductor device.

10. The semiconductor device of claim 5 wherein the voltage level detector comprises a multi-level voltage detector for generating a clock selection signal as the voltage control signal, and wherein the controller includes a clock signal selector for selecting one of a plurality of clock signals to control the operation frequency of the high voltage generating circuit.

11. The semiconductor device of claim 10 further comprising a plurality of clock signal dividers receiving a base clock signal and coupled in series to generate the plurality of clock signals.

12. A method of controlling power efficiency in a semiconductor device comprising a high voltage generating circuit for generating a voltage signal having a high voltage level, the method comprising the steps of:
enabling the high voltage generating circuit in response to detecting a voltage level lower than a first predetermined voltage level and disabling the high voltage generating circuit in response to detecting a voltage level higher than a second predetermined voltage level such that the high voltage generating circuit provides an output signal at a relatively constant high voltage level, wherein the second predetermined voltage level is higher than the first predetermined voltage level.

13. The method of claim 12 wherein the semiconductor device further comprises a clock oscillator circuit coupled to the high voltage generating circuit, and wherein the step of enabling and disabling the high voltage generating circuit comprises the step of turning on the clock oscillator circuit in response to detecting a voltage level lower than a first predetermined voltage level and turning off the clock oscillator circuit in response to detecting a voltage level higher than a second predetermined voltage level such that the high voltage generating circuit provides an output signal at a relatively constant high voltage level.

14. The method of claim 12 wherein the first predetermined voltage is 7.0 volts and wherein the second predetermined voltage level is 7.5 volts.

15. The method of claim 12 wherein the first and second predetermined voltage levels define a high efficiency operating range for the high voltage generating circuit.

16. The method of claim 15 wherein the high efficiency operating range for the high voltage generating circuit is 0.5 volts wide.

17. A semiconductor device comprising:
a high voltage generating circuit for providing at an output thereof a voltage signal having a high voltage level;
a voltage level detector coupled to the output of the high voltage generating circuit for generating a voltage control signal in response to the high voltage level detected thereat; and
a controller coupled to the voltage level detector and the high voltage generating circuit to enable the high voltage generating circuit in response to detecting a voltage level lower than a first predetermined voltage level and to disable the high voltage generating circuit in response to detecting a voltage level higher than a second predetermined voltage level such that the high voltage generating circuit provides an output signal at a relatively constant high voltage level, wherein the second predetermined voltage level is higher than the first predetermined voltage level.

18. The semiconductor device of claim 17 wherein the controller includes a clock oscillator circuit coupled to the high voltage generating circuit for providing an operation frequency control signal thereto for driving the high voltage generating circuit, and wherein the controller enables and disables the high voltage generating circuit by turning on and turning off the clock oscillator circuit.

19. The semiconductor device of claim 17 further comprising a large capacitor coupled to the output of the high voltage generating circuit to provide a relatively constant output current thereat.

20. The semiconductor device of claim 17 wherein the high voltage generating circuit is a drain pump.
